(19) United States
(12) Patent Application Publication
(10) Pub. No.: US 2003/0178143 A1
(43) Pub. Date: Sep. 25, 2003

(54) Plasma reactor with plural independently driven concentric coaxial waveguides

(75) Inventor: Mark Perrin, San Jose, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/106,703

(22) Filed: Mar. 25, 2002

(51) Int. Cl. C23F 1/00; C23C 16/00

(52) U.S. Cl. 156/345.41; 118/723 MW

(57) ABSTRACT

A plasma reactor includes a vacuum chamber having an interior and a pedestal within the chamber for supporting a semiconductor wafer to be processed. Gas distribution apparatus introduces a process gas into said chamber. Power is applied to the chamber by plural concentric coaxial waveguides outside of said chamber having an axis of propagation pointing toward the interior of said chamber and establishing corresponding annular zones of radiation within said chamber. The reactor further includes apparatus that can apply different levels of electromagnetic radiation power to different ones of the plural concentric coaxial waveguides.

### BACKGROUND

1. Technical Field

The invention concerns a plasma reactor for processing a semiconductor wafer using microwaves for plasma source power.

2. Background Art

Plasma reactors are employed in semiconductor wafer processing for etching thin films such as silicon dioxide, silicon and aluminum films and for depositing thin films such as an epitaxial silicon layer. For example, in a typical silicon dioxide etch process, a crystalline silicon wafer is placed in a vacuum chamber of the plasma reactor and a process gas containing a fluorine compound is introduced into the reactor. An electromagnetic source of energy, such as microwaves or RF power, is applied to the chamber to ionize the process gas, thereby producing free fluorine. In a chemical vapor deposition process, a similar procedure is followed except that the process gas contains a compound of the species (e.g., silicon) to be deposited as an epitaxial layer.

In either an etch process or a chemical vapor deposition process, the uniformity with which the process is carried out across the wafer surface determines whether the process succeeds. As device geometries continue to shrink and device densities climb in the microelectronic industry, process uniformity must improve. A principal factor in determining process uniformity is distribution of plasma ion density across the wafer surface. This is because plasma ion density determines various key parameters in a plasma process. For example, plasma ion density determines etch rate in a plasma assisted etch process and determines deposition rate in a plasma assisted chemical vapor deposition process. Such parameters must be uniform across the wafer surface. Otherwise, an etch process, for example, will cause overetching of devices in one zone of the wafer and underetching of devices in other zones of the wafer.

One of the principal factors determining plasma ion density distribution at the wafer surface is the distribution of plasma source power density within the chamber. A key aspect of plasma ion density distribution is the radial distribution of plasma ion density. In plasma reactors in which plasma source power is applied by microwave power applicators, there is a need to adjust or improve the uniformity of the radial distribution of plasma ion density across the wafer surface. For example in some cases, plasma ion density is greater in one zone (e.g., near the wafer center) and less in another zone (e.g., near the wafer periphery. There is a need to reduce such non-uniformity by adjusting the radial distribution of plasma ion density without having to replace or redesign elements of the reactor chamber with each adjustment.

### SUMMARY

A plasma reactor includes a vacuum chamber having an interior with a vacuum pump coupled to the chamber and a pedestal within the chamber for supporting a semiconductor wafer to be processed. Gas distribution apparatus introduces a process gas into said chamber. Power is applied to the chamber by plural concentric coaxial waveguides outside of said chamber having an axis of propagation pointing toward the interior of said chamber and establishing corresponding annular zones of radiation within said chamber. The reactor further includes apparatus that can apply different levels of electromagnetic radiation power to different ones of the plural concentric coaxial waveguides.

In one embodiment, the apparatus that can apply different levels of electromagnetic radiation power are plural electromagnetic wave power sources coupled to respective ones of the plural concentric waveguides, each of the plural electromagnetic wave power sources being adjustable relative to one another for adjustment of electromagnetic radiation power within each of the annular radiation zones of said chamber.

In another embodiment, each of the plural concentric waveguides has an annular input end facing away from the chamber for receiving electromagnetic radiation, and the apparatus that can apply different levels of electromagnetic radiation power is a single coaxial waveguide having an input end and an output end, the output end being coupled to the annular input end of each of said plural concentric coaxial waveguides. An electromagnetic wave power source is coupled to the single concentric waveguide. The different amount of radiation apportioned to the different concentric coaxial waveguides is determined by tuning the openings of the input ends of the different waveguides.

### BRIEF DESCRIPTION OF THE DRAWINGS

FIG. 1 is a diagram of a plasma reactor of a first embodiment.

FIG. 2 depicts a waveguide power applicator of the embodiment of FIG. 1.

FIG. 3 is a plan view corresponding to FIG. 2.

FIG. 4 depicts a waveguide power applicator in accordance with a second embodiment.

FIG. 5 depicts a waveguide power applicator in accordance with a third embodiment.

FIG. 6 depicts a waveguide power applicator in accordance with a fourth embodiment.

FIG. 7 is a plan view corresponding to FIG. 6.

FIG. 8 depicts a waveguide power applicator in accordance with a fifth embodiment.

FIG. 9 depicts a waveguide power applicator in accordance with a sixth embodiment.

FIG. 10 depicts one implementation of the embodiment of FIG. 8.

FIG. 11 depicts a second implementation of the embodiment of FIG. 8.

FIG. 12 depicts a third implementation of the embodiment of FIG. 8.

FIG. 13 illustrates a mechanical shutter of the type employed in the implementation of FIG. 12.

FIG. 14 depicts a waveguide power applicator in accordance with a seventh embodiment.

FIG. 15 depicts a waveguide power applicator in accordance with an eighth embodiment.

FIG. 16 depicts a waveguide power applicator in accordance with a ninth embodiment.

FIGS. 17A, 17B and 17C illustrate, respectively, plasma radial density distribution produced by a radially uniform power source, a power density radial pattern that the illustrated embodiments are capable of producing, and an improved radial distribution of plasma density produced by the power density distribution of FIG. 17B.

### DETAILED DESCRIPTION

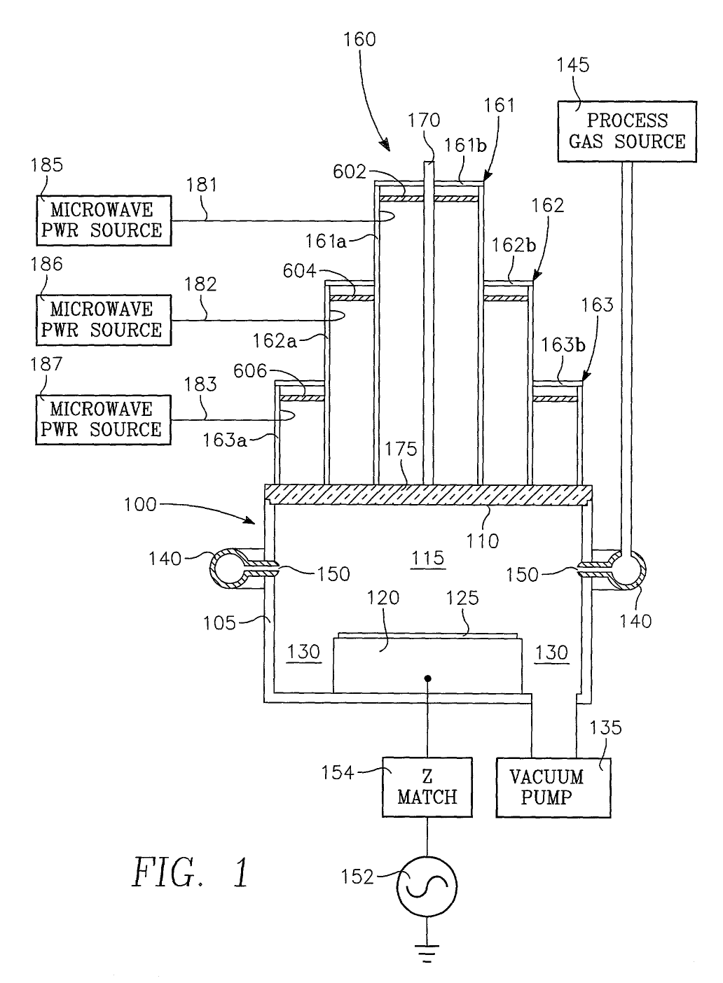

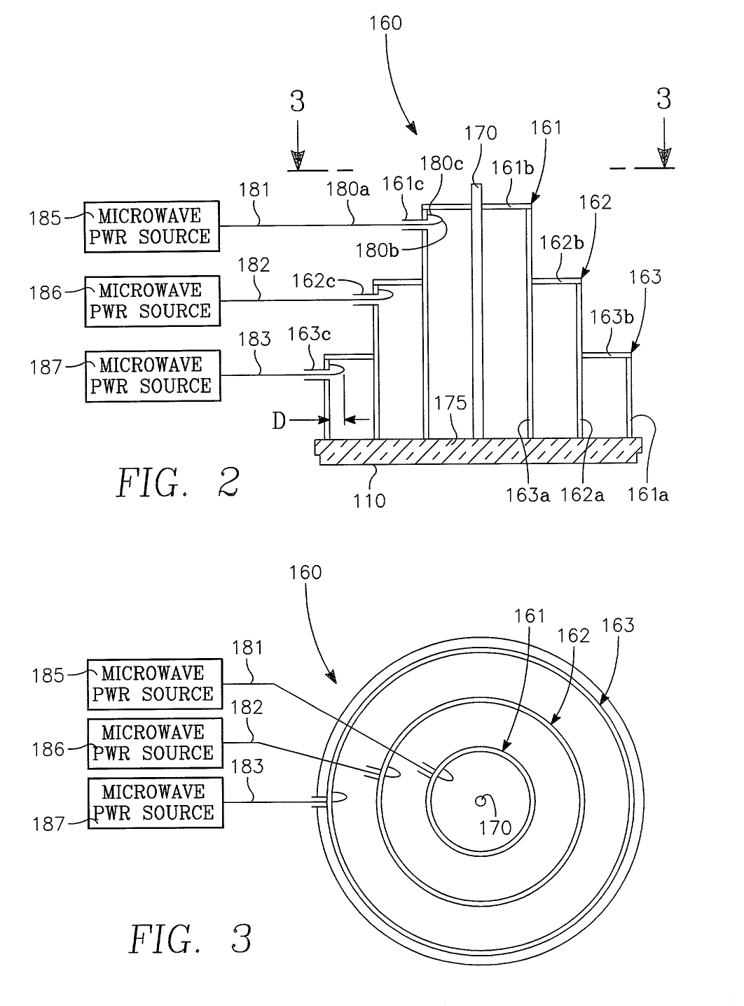

Referring to FIGS. 1, 2 and 3, a plasma reactor 100 includes a side wall 105 and a ceiling 110 defining a vacuum chamber 115. The chamber 115 houses a wafer support pedestal 120 for supporting a semiconductor wafer 125 to be processed. A pumping annulus 130 is coupled at the floor of the chamber 100 to a vacuum pump 135. A gas manifold 140 furnishes process gas from as gas supply 145 to plural orifices or gas injection nozzles 150 that spray gas into the chamber 100. FIG. 1 shows plural gas injection nozzles 150 extending through the side wall 105. In other implementations, the process gas may be injected through plural gas injection orifices in another part of the chamber, such as the ceiling 110 for example.

Microwave power is applied to the chamber interior by a coaxial waveguide 160 facing the ceiling 110. The axis of the waveguide 160 can be at least nearly parallel and coincident with the axis of the wafer 125, of the pedestal 120 and of the chamber 100, as shown in FIG. 1. However, the axis of the waveguide 160 may be non-parallel and/or non-coincident with the axis of the wafer 125, the pedestal 120 or the chamber 100.

The coaxial waveguide 160 consists of plural concentric coaxial waveguides 161, 162, 163 with an axial conductor 170 along the axis of the coaxial waveguide 160. The three concentric coaxial waveguides 161, 162, 163 consist of respective concentric cylindrical conductors 161a, 162a, 163a terminated at the bottom in a quartz window 175 that constitutes the ceiling 110 of the chamber 100. The three waveguides 161, 162, 163 are terminated at the top by flat annular conductors 161b, 162b, 163b. The axial conductor 170 is the center conductor of the innermost coaxial waveguide 161. The innermost coaxial waveguide 161 functions as the center conductor of the intermediate coaxial waveguide 162. The intermediate coaxial waveguide 162 functions as the center conductor of the outermost coaxial waveguide 163.

In accordance with an optional feature, the waveguides 161, 162, 163 can be tuned individually with respective conductive annular plungers 602, 604, 606 inside the input ends of the respective waveguides 161, 162, 163 by axially moving any one or all of the plungers 602, 604, 606. Each of the plungers 602, 604, 606 is in electrical contact with the respective waveguide.

Microwave power is coupled into the waveguides 161, 162, 163 by respective wire or rod radiators 181, 182, 183 protruding into the top portion of the corresponding waveguides 161, 162, 163. Each of the wire radiators 181, 182, 183 is connected to an independently adjustable microwave power source 185, 186, 187, respectively. The three microwave sources 185, 186, 187 may be a separate microwave generator, such as a magnetron and may include an impedance matching circuit of the type well-known in the art. Alternatively, the three microwave sources 185, 186, 187 may be a single microwave generator and a three-way power splitter that produces three microwave outputs whose power levels may be adjusted relative to one another.

Microwave propagation in the coaxial waveguides 161, 162, 163 is in the transverse electric mode (TEM) in which the electric field is radial while the magnetic field is circular. The coaxial waveguides 161, 162, 163 contribute to uniform distribution of microwave power across the wafer surface because their cylindrical symmetry corresponds to the cylindrical symmetry of the chamber 100 and the cylindrical symmetry of the wafer 125. The coaxial waveguides 161, 162, 163 provide much greater bandwidth than other types of waveguides, since coaxial waveguides generally can support a broad spectrum of electromagnetic radiation both within and below microwave frequencies. The three waveguides 161, 162, 163 establish three annular zones over the wafer 125 within which microwave power density is independently adjustable. This feature solves the problem of non-uniform radial distribution of plasma ion density, because it enables the adjustment of the radial distribution of microwave power over the wafer surface in order to adjust or optimize the radial distribution of plasma ion density. For example, if a uniform application of the microwave power to each of the three waveguides 161, 162, 163 produces a non-uniform center-high radial distribution of plasma ion density at the wafer surface, then a more uniform distribution of plasma ion density may be realized by applying less power to the innermost waveguide 161 and the most power to the outermost waveguide 163.

In the embodiment of FIG. 1, the three waveguides 161, 162, 163 have different axial lengths that increase from the outermost to the innermost waveguide so as to permit free access of each of the wire radiators 181, 182, 183 to the corresponding waveguide. However, in other embodiments the three waveguides can be of the same length.

In the embodiment of FIGS. 1-3, each wire radiator 181, 182, 183 consists of a thin straight conductor 180a that passes through an entry hole 161c, 162c, 163c in the respective waveguide and penetrates into the interior of the waveguide by a selected distance D, a 180 degree loop 180b and a second straight conductor 180c extending from the loop 180b and terminated on the interior surface of the waveguide near the entry hole. The penetration distance D is selected to optimize the impedance match between the wire radiator and the waveguide at the frequency of the power source 185, 186, 187.

The axial lengths of the waveguides 161, 162, 163 may be varied since the coaxial waveguides are very broadband devices, as noted above. However, their lengths may be selected to achieve resonance and/or impedance match at the frequency of the power source 185, 186, 187 using conventional analytical techniques. Alternatively or in addition, each source 185, 186, 187 may have its own impedance match device functioning in the conventional manner to minimize power reflected back to the source.

If the three power sources 185, 186, 187 are independent, then the user may select, if desired, a different frequency for each one and select the corresponding waveguide axial length and wire radiator penetration distance D accordingly.

While FIGS. 1-3 illustrate three concentric coaxial waveguides 161, 162, 163 within the waveguide 160, other embodiments may include any other number of concentric waveguides from as few as two to as many as desired. A greater number of concentric waveguides enables a finer adjustment of radial distribution of power across the wafer surface.

While the description of the embodiment of FIGS. 1-3 refers to the application of microwave power, frequencies other than microwave frequencies may be employed, since the coaxial waveguide 160 is a broadband device. For example, radio frequencies (UHF, VHF or HF) may be employed instead of microwave frequencies. Such different frequency selections may entail careful selection of various impedance matching measures, such as waveguide axial length, wire radiator penetration distance or use of dynamic impedance matching devices.

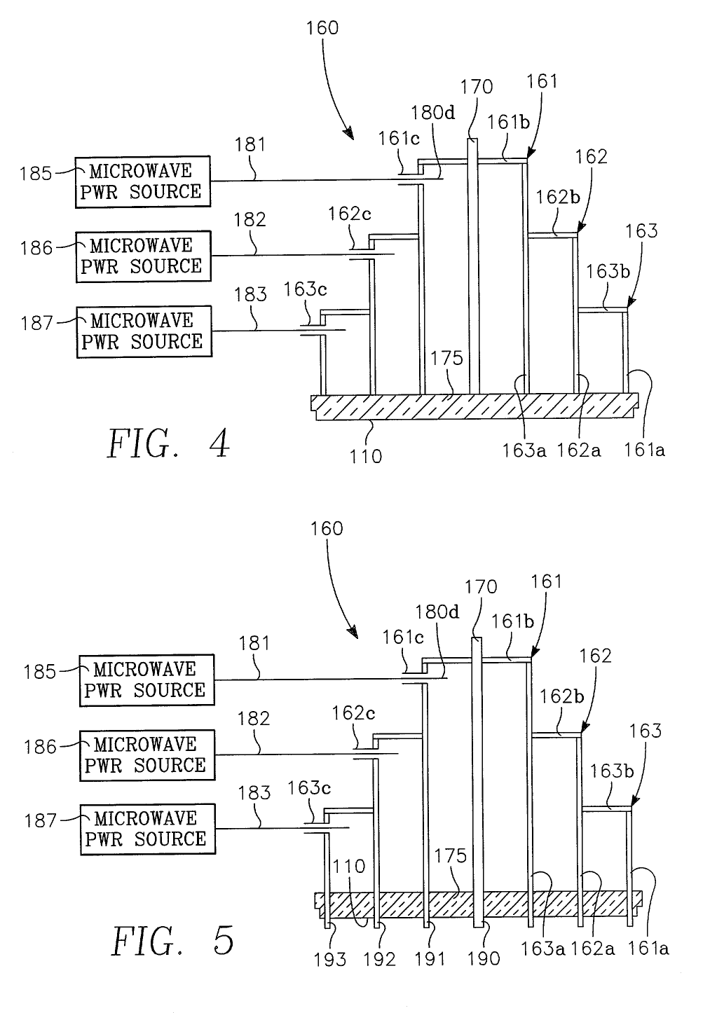

FIG. 4 illustrates an embodiment in which the loop 180b and the second straight section 180c of each wire radiator 181, 182, 183 are eliminated, so that each wire resonator is simply a straight wire.

FIG. 5 illustrates and embodiment in which cross-coupling through the quartz window 175 between various ones of the concentric waveguides 161, 162, 163 and mode generation within the quartz window 175 are prevented (or reduced) by the introduction of thin conductive cylindrical barriers 191, 192 within the quartz window 175 that separate the quartz window 175 into separate annular sections. The conductive cylindrical barriers 191, 192 coincide with respective ones of the cylindrical conductive walls 161a, 162a of the concentric waveguides 161, 162.

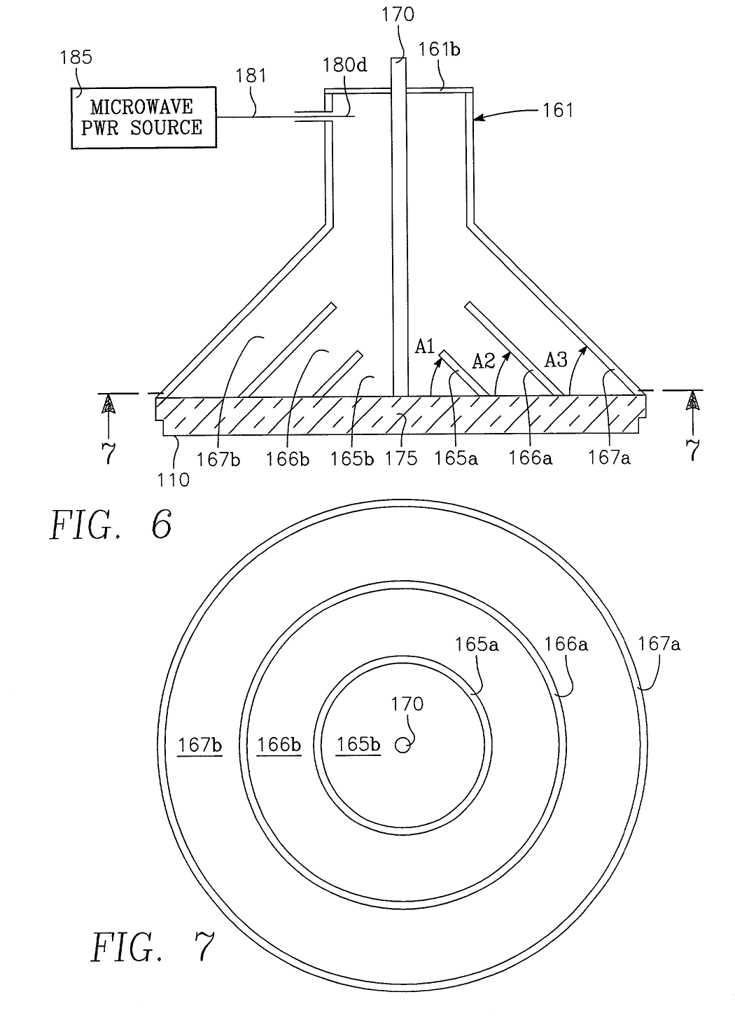

Referring to FIGS. 6 and 7, power may be selectively apportioned among the three annular zones referred to above while using only a single power source with a single wire radiator to a single waveguide. Specifically, a single wire radiator 180 couples power near the top of a single coaxial waveguide 160. The coaxial waveguide 160 is coupled at its bottom to three concentric waveguides 165, 166, 167 that receive respective predetermined portions of the power transmitted through the single waveguide 160. In the embodiment of FIG. 6, the three concentric waveguides 165, 166, 167 are conical and consist of respective conical thin conductive walls 165a, 166a, 167a. The angles A1, A2, A3 of the conical walls 165a, 166a, 167a, respectively, are selected to minimize the change in radiation direction in the transition between the single waveguide 160 and the three conical waveguides 165, 166, 167, thereby reducing reflections at the transition or interface. Each waveguide 165, 166, 167 forms an annular opening 165b, 166b, 167b facing the waveguide 160. The areas of the openings 165b, 166b, 167b determine the apportionment among the three concentric waveguides 165, 166, 167 of power received from the waveguide 160. Thus, like the embodiment of FIG. 1, the embodiment of FIG. 6 provides plural radial zones over the wafer 125 beneath the respective waveguides 165, 166, 167 in which different levels of power may be applied to achieve more nearly uniform radial distribution of power across the entire wafer.

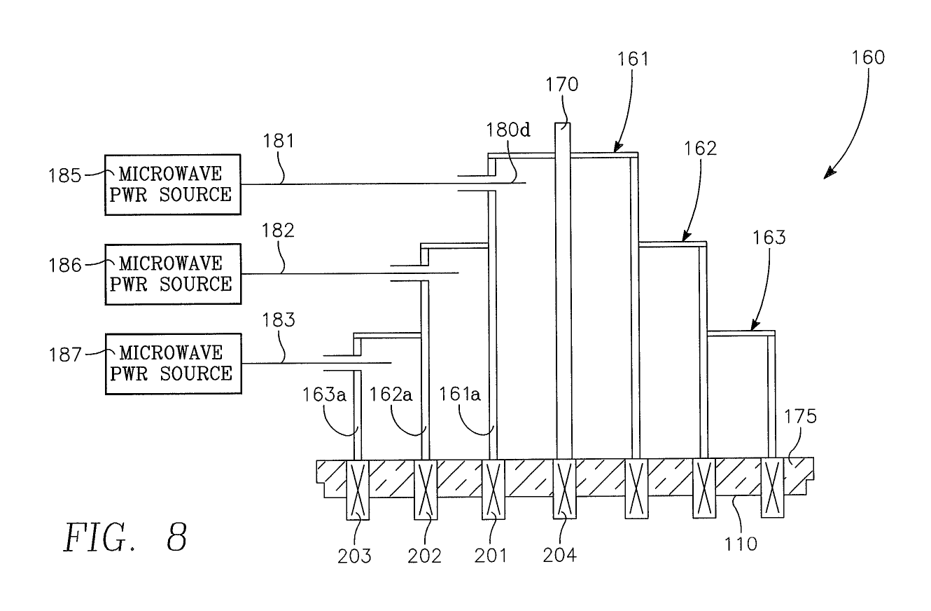

Referring to FIG. 8, electron cyclotron resonance may be achieved in the embodiment of FIG. 4 by providing concentric ring magnets 201, 202, 203 and a center pole magnet 204 coinciding, respectively, with the outermost cylindrical conductor wall 163a, the intermediate cylindrical conductor wall 162a, the innermost cylindrical conductor wall 161a and the center conductor 170. In the embodiment of FIG. 8, these magnets are placed within the quartz window 175, although they may be placed in other suitable locations near the waveguides 161, 162, 163. The skilled worker can readily select the appropriate magnet strengths and microwave frequencies for electron cyclotron resonance in the embodiment of FIG. 8.

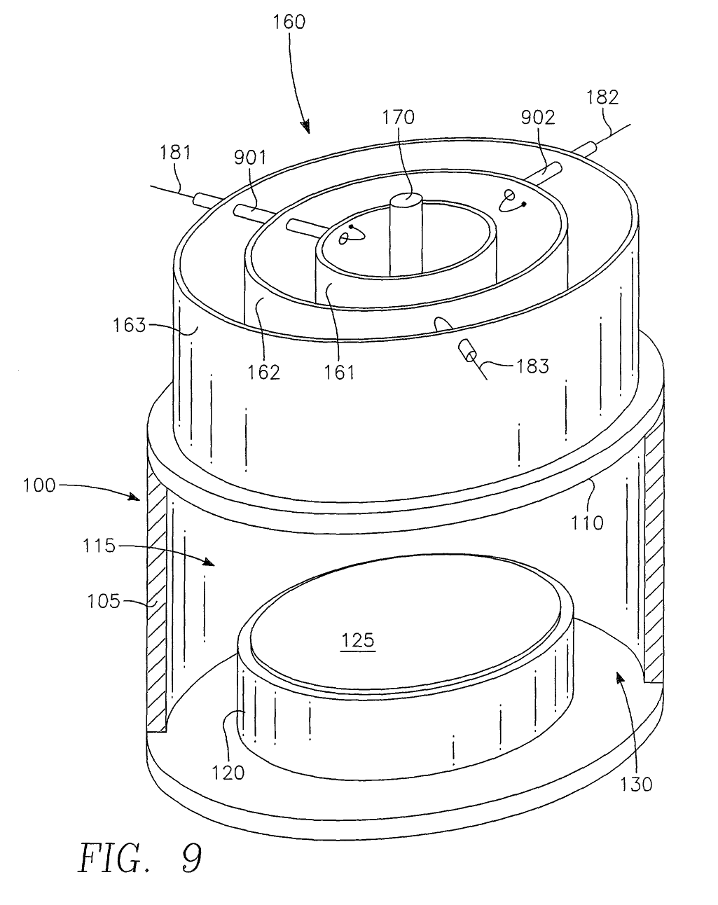

FIG. 9 illustrates how the concentric waveguides 161, 162, 163 may be of the same axial length and the wire radiators 181, 182, 183 may be fed at different angles about the central axis. The wire radiator 181 that excites the innermost waveguide 161 is fed through the intermediate and outermost waveguides 162, 163 through a cylindrical conductive shield 901. The shield 901 prevents or reduces radiation from the wire radiator 161 into all but the innermost waveguide 161. Similarly, the wire radiator 182 that excites the intermediate waveguide 162 is fed through the outermost waveguide 163 through a cylindrical conductive shield 902.

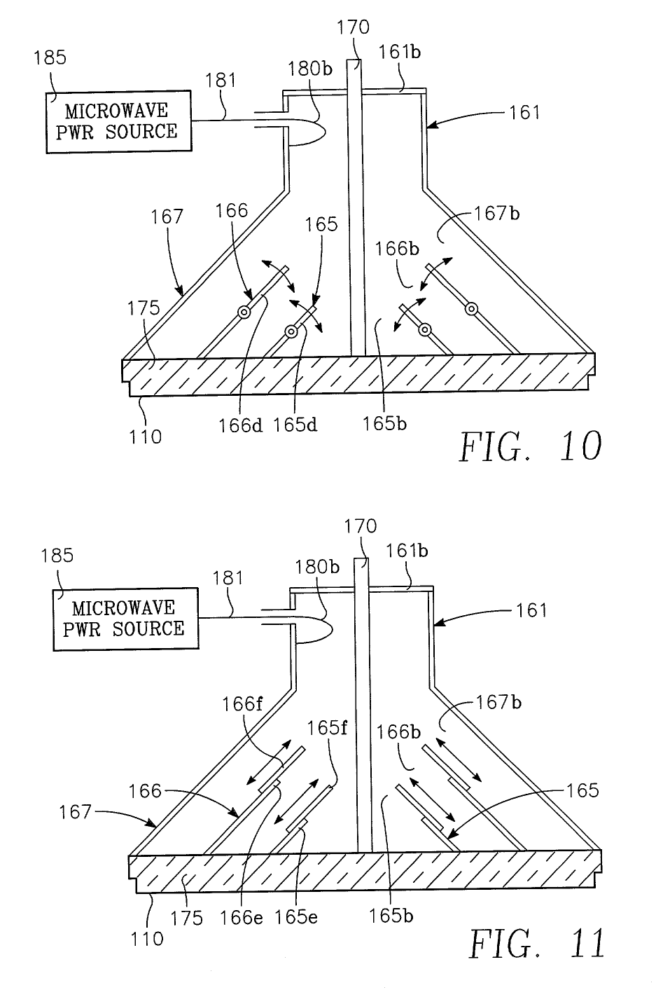

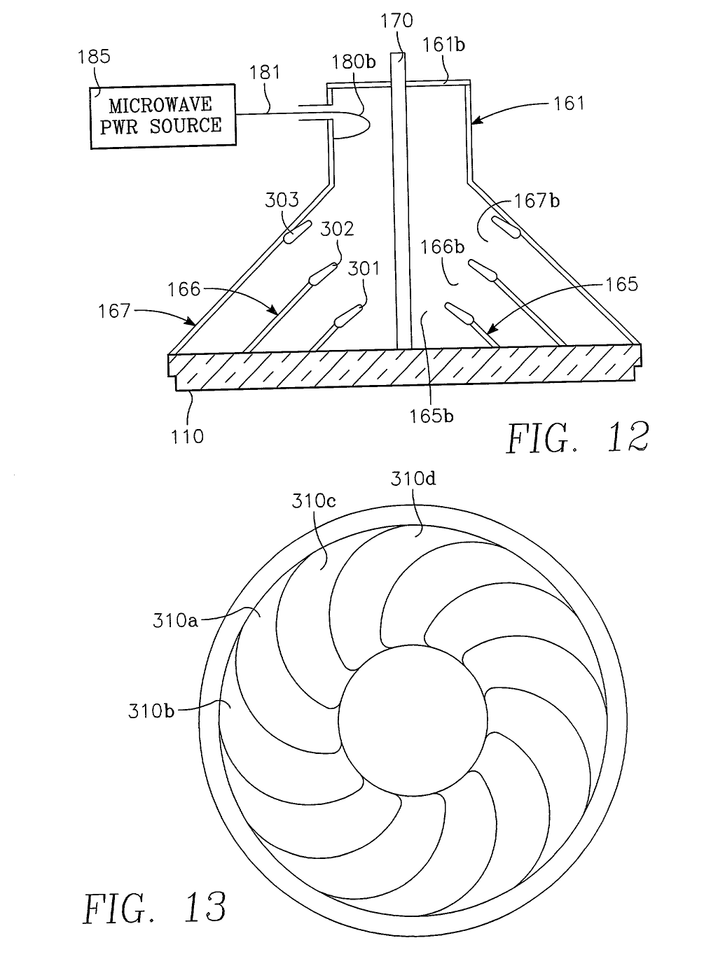

FIG. 10 illustrates one way the embodiment of FIG. 6 may be adapted to provide variable apportionment of microwave power among the three conical waveguides 165, 166, 167. Specifically, the top sections 165d 166d of the conical cylindrical walls of the conical waveguides 165, 166 may be articulated at least slightly, with some elastic deformation of the walls, to change the area of any one or all of the openings 165b, 166b, 167b. Thus, some openings may be made to be larger than others so that different amounts of power may be apportioned among the three conical waveguides 165, 166, 167. FIG. 11 illustrates another way of adjusting the areas of individual ones of the openings 165b, 166b, 167b by providing slidable conical conductors 165f, 166f, around corresponding ones of the top sections 165d, 166d. The slidable conductors may be moved along the surfaces of the respective conical walls to at least slightly change the areas of individual ones of the openings 165b, 166b, 167b. FIG. 12 illustrates yet another way of mechanically adjusting the areas of individual ones of the openings 165b, 166b, 167b using shutter-like adjustable openings 301, 302, 303. A single shutter opening typical of the three shutter openings 301, 302, 303 is illustrated in FIG. 13. While the shutter openings 301, 302, 303 may lie in planes perpendicular to the axis of symmetry, in the embodiment of FIG. 12 they conform to the conical angle of the respective conical walls of the waveguides 165, 166, 167, and thereby provide a smoother transition at the boundary between the single waveguide 160 and the conical waveguides 161, 162, 163.

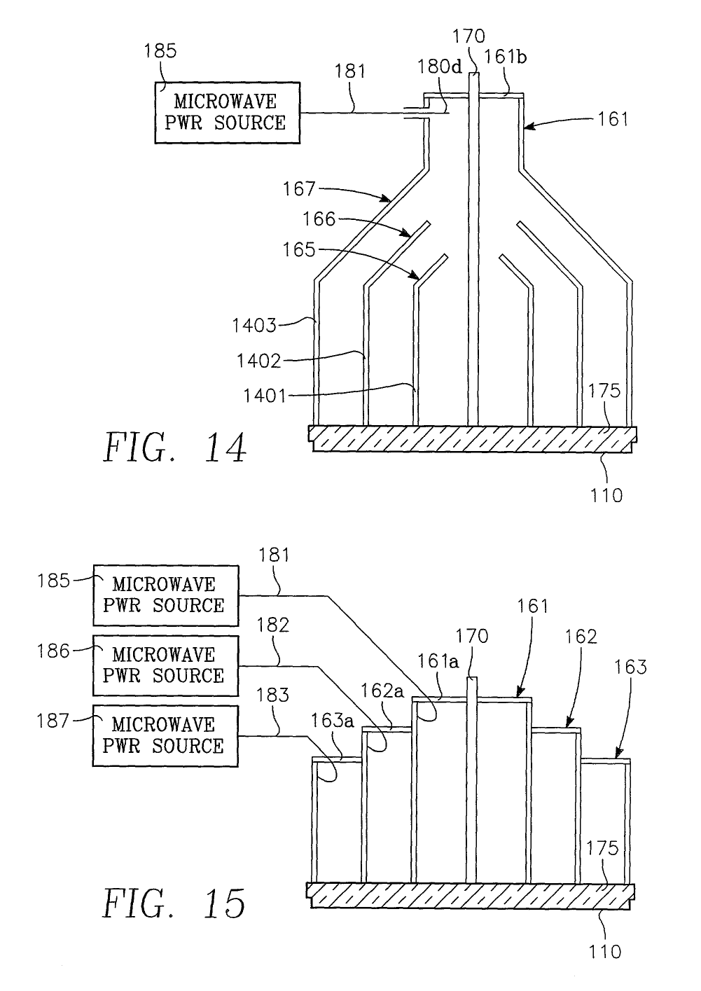

FIG. 14 illustrates how the three waveguide 165, 166, 167 of FIG. 6 may elongated by adding three concentric cylindrical waveguides 1401, 1402, 1403 at the bottom of the three conical waveguides 165, 166, 167.

While the wire radiators 181, 182, 183 of FIG. 1 extend into the respective waveguides 161, 162, 163 in a direction perpendicular to the axis of symmetry, FIG. 15 illustrates that the wire radiators 181, 182, 183 may extend into the respective waveguides 161, 162, 163 at an angle other than perpendicular to the axis of symmetry. FIG. 16 illustrates how the wire radiators 181, 182, 183 may extend into the respective waveguides 161, 162, 163 in a direction parallel to the axis of symmetry but at respective radii corresponding to the annuli defined by the respective waveguides 161, 162, 163.

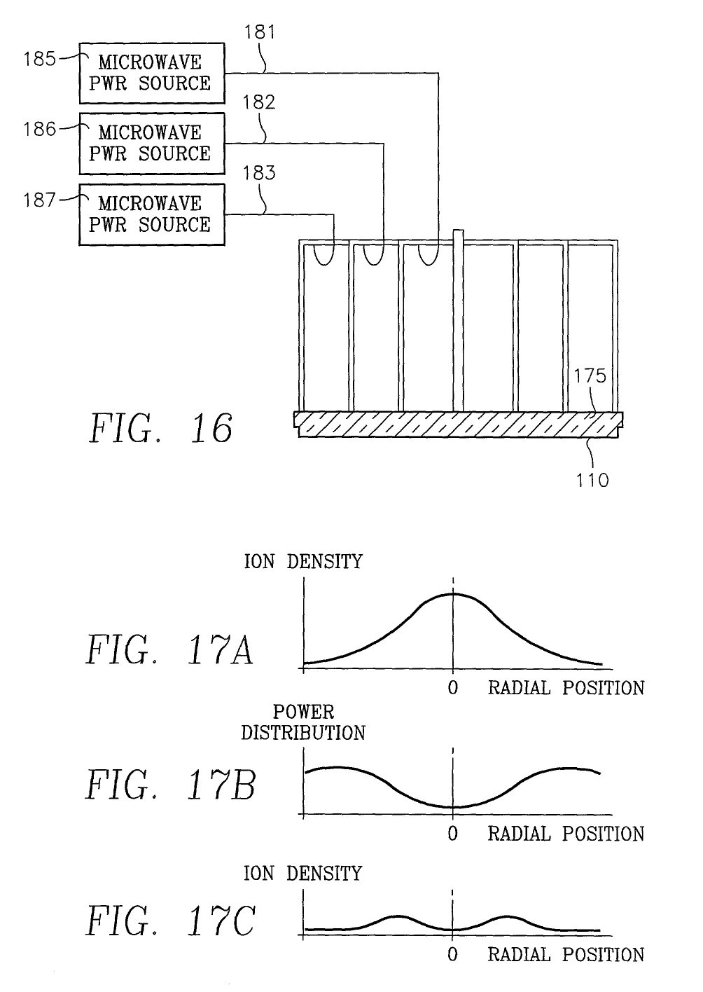

FIGS. 17A, 17B and 17C illustrate how the adjustment of the radial pattern of applied microwave power at the chamber ceiling can improve uniformity of plasma ion density at the wafer surface. FIG. 17A illustrates how plasma ion density at the surface of the wafer 125 tends to have a center-high radial distribution relative to the axis of symmetry of the chamber 100. This may tend to occur when plasma source power is applied in a fairly uniform radial pattern at the ceiling, as it is in a typical reactor. FIG. 17B illustrates a center-low apportionment of microwave power among the three waveguides 161, 162, 163 that may be selected to compensate for the nonuniform distribution of plasma ion density illustrated in FIG. 1. In the example of FIG. 17B, the least amount of microwave power is coupled to the innermost waveguide 161, a moderate amount of microwave power is applied to the intermediate waveguide 162 and the greatest amount of microwave power is applied to the outermost waveguide 163. The severity of the differences between the respective amounts of microwave power applied to the three waveguides 161, 162, 163 is selected according to the severity of the nonuniformity of the center-high radial distribution of plasma ion density of FIG. 17A. FIG. 17C illustrates the resulting radial distribution of microwave power across the surface of the wafer 125 produced by the center-low apportionment of microwave power in the waveguides 161, 162, 163 depicted in FIG. 17B. The radial distribution of microwave power at the wafer surface illustrated in FIG. 17C has better uniformity than that of FIG. 17A. This is because the center-low apportionment of microwave power among the three concentric waveguides 161, 162, 163 enhances plasma density at the wafer periphery while attenuating it at the wafer center.

While the invention has been described in detail with reference to preferred embodiments, it is understood that variations and modifications thereof may be made without departing from the true spirit and scope of the invention.

What is claimed is:

1. A plasma reactor comprising:
a vacuum chamber having an interior;
a pedestal within said chamber for supporting a workpiece to be processed;
gas distribution apparatus for introducing a process gas into said chamber;
plural concentric coaxial waveguides outside of said chamber and having an axis of propagation pointing toward the interior of said chamber and establishing corresponding annular zones of radiation within said chamber; and
plural electromagnetic wave power sources coupled to respective ones of said plural concentric waveguides, each of said plural electromagnetic wave power sources being adjustable relative to one another for adjustment of electromagnetic radiation power within each of said annular radiation zones of said chamber.

2. The reactor of claim 1 wherein said axis of propagation of said plural concentric coaxial waveguides coincides with an axis of symmetry of said pedestal, whereby said annular radiation zones correspond to annular zones over said workpiece.

3. The reactor of claim 1 wherein said plural concentric waveguides comprise:
a cylindrical center conductor extending along said propagation axis;
an inner cylindrical waveguide conductive wall concentric with said center conductor and defining an inner annular volume between said inner cylindrical waveguide and said center conductor;
an outer cylindrical waveguide conductive wall concentric with said inner cylindrical waveguide conductive wall and enclosing an outer annular conductive volume.

4. The reactor of claim 3 further comprising an intermediate cylindrical waveguide conductive wall between and concentric with said inner and outer cylindrical waveguide conductive walls, said intermediate cylindrical waveguide conductive wall defining an intermediate annular conductive volume between said intermediate and inner cylindrical conductive waveguide walls, said outer annular volume lying between said outer and intermediate cylindrical conductive walls.

5. The reactor of claim 3 further comprising:
plural wire radiators coupled to respective ones of said electromagnetic radiation power sources, said plural wire radiators extending into and terminated within the interior spaces enclosed by respective ones of said plural concentric waveguides.

6. The reactor of claim 5 wherein said plural wire radiators extend radially with respect to said coaxial waveguides.

7. The reactor of claim 5 wherein said plural wire radiators extend axially with respect to said coaxial waveguides.

8. The reactor of claim 5 wherein said plural wire radiators extend at angles between radial and axial directions with respect to said coaxial waveguides.

9. The reactor of claim 5 wherein said plural wire radiators are terminated within the annular volumes of respective ones of said concentric waveguides by open ends of said plural wire radiators.

10. The reactor of claim 5 wherein each of said plural wire radiators loops within the annular volume of the corresponding concentric waveguide and is terminated on an interior surface of the corresponding waveguide wall.

11. The reactor of claim 8 further comprising a window at an end of said plural concentric waveguides facing said chamber.

12. The reactor of claim 11 wherein said window forms a portion of a vacuum enclosure of said chamber.

13. The reactor of claim 11 wherein said window is formed of a dielectric material.

14. The reactor of claim 13 wherein said window comprises quartz.

15. The reactor of claim 11 further comprising annular walls enclosing ends of respective ones of said concentric cylindrical waveguides opposite from said window, whereby each waveguide extends from a corresponding one of said annular walls to said window.

16. The reactor of claim 11 further comprising conductive barriers separating said window into annular sections corresponding to said concentric cylindrical waveguides.

17. The reactor of claim 11 further comprising plural ring magnets within said window in registration with corresponding walls of said concentric cylindrical waveguides.

18. The reactor of claim 1 wherein said electromagnetic radiation power sources are microwave power sources.

19. The reactor of claim 1 wherein said electromagnetic radiation power sources are RF power sources.

20. The reactor of claim 1 wherein said plural concentric waveguides are of the same axial length.

21. The reactor of claim 1 wherein axial lengths of said plural concentric waveguides increase from the outermost to the innermost ones of said concentric waveguides.

22. A power applicator of a plasma reactor for processing a workpiece, said power applicator terminated in a window of said plasma reactor and comprising:
plural concentric coaxial waveguides having an axis of propagation pointing toward the interior of said reactor and establishing corresponding annular zones of radiation within said reactor; and
plural electromagnetic wave power sources coupled to respective ones of said plural concentric waveguides, each of said plural electromagnetic wave power sources being adjustable relative to one another for adjustment of electromagnetic radiation power within each of said annular radiation zones of said reactor.

23. The apparatus of claim 22 wherein said plural concentric waveguides comprise:
a cylindrical center conductor extending along said propagation axis;
an inner cylindrical waveguide conductive wall concentric with said center conductor and defining an inner annular volume between said inner cylindrical waveguide and said center conductor;
an outer cylindrical waveguide conductive wall concentric with said inner cylindrical waveguide conductive wall and enclosing an outer annular conductive volume.

24. The apparatus of claim 23 further comprising an intermediate cylindrical waveguide conductive wall between and concentric with said inner and outer cylindrical waveguide conductive walls, said intermediate cylindrical waveguide conductive wall defining an intermediate annular conductive volume between said intermediate and inner cylindrical conductive waveguide walls, said outer annular volume lying between said outer and intermediate cylindrical conductive walls.

25. The apparatus of claim 23 further comprising:
plural wire radiators coupled to respective ones of said electromagnetic radiation power sources, said plural wire radiators extending into and terminated within the interior spaces enclosed by respective ones of said plural concentric waveguides.

26. The apparatus of claim 25 wherein said plural wire radiators extend radially with respect to said coaxial waveguides.

27. The apparatus of claim 25 wherein said plural wire radiators extend axially with respect to said coaxial waveguides.

28. The apparatus of claim 25 wherein said plural wire radiators extend at angles between radial and axial directions with respect to said coaxial waveguides.

29. The apparatus of claim 5 wherein said plural wire radiators are terminated within the annular volumes of respective ones of said concentric waveguides by open ends of said plural wire radiators.

30. The apparatus of claim 25 wherein each of said plural wire radiators loops within the annular volume of the corresponding concentric waveguide and is terminated on an interior surface of the corresponding waveguide wall.

31. A plasma reactor comprising:
a vacuum chamber having an interior;
a pedestal within said chamber for supporting a workpiece to be processed;
gas distribution apparatus for introducing a process gas into said chamber;
plural concentric coaxial waveguides outside of said chamber and having an axis of propagation pointing toward the interior of said chamber and establishing corresponding annular zones of radiation within said chamber, each of said plural concentric waveguides having an annular input end facing away from said chamber for receiving electromagnetic radiation;
a single coaxial waveguide having an input end and an output end, the output end being coupled to the annular input end of each of said plural concentric coaxial waveguides;
an electromagnetic wave power source coupled to said single concentric waveguide.

32. The reactor of claim 31 wherein said annular input ends of the plural concentric waveguides have respective areas determining amounts of electromagnetic radiation power from said single coaxial waveguide apportioned to respective ones of said plural concentric waveguides.

33. The reactor of claim 32 wherein said plural concentric coaxial waveguides are conically shaped having a lesser radius near said single coaxial waveguide and a greater radius facing said chamber while said single waveguide is cylindrical.

34. The reactor of claim 32 further comprising movable elements whose positions determine areas of corresponding ones of said input ends of said plural concentric waveguides.

35. The reactor of claim 34 wherein said movable elements comprise mechanical shutters.

36. The reactor of claim 31 further comprising:
a single wire radiator having one end connected to said electromagnetic wave power source and another end inside an interior space of said single coaxial waveguide.

37. A plasma reactor comprising:
a vacuum chamber having an interior;
a pedestal within said chamber for supporting a workpiece to be processed;
gas distribution apparatus for introducing a process gas into said chamber;
plural concentric coaxial waveguides outside of said chamber and having an axis of propagation pointing toward the interior of said chamber and establishing corresponding annular zones of radiation within said chamber; and
means for applying different levels of electromagnetic radiation power to different ones of said plural concentric coaxial waveguides.

38. The reactor of claim 37 wherein said means for applying different levels of electromagnetic radiation power comprise:
plural electromagnetic wave power sources coupled to respective ones of said plural concentric waveguides, each of said plural electromagnetic wave power sources being adjustable relative to one another for adjustment of electromagnetic radiation power within each of said annular radiation zones of said chamber.

39. The reactor of claim 37 wherein each of said plural concentric waveguides has an annular input end facing away from said chamber for receiving electromagnetic radiation, said means for applying different levels of electromagnetic radiation power comprising:
a single coaxial waveguide having an input end and an output end, the output end being coupled to the annular input end of each of said plural concentric coaxial waveguides;
an electromagnetic wave power source coupled to said single concentric waveguide.

40. The reactor of claim 39 wherein said annular input ends of the plural concentric waveguides have respective areas determining amounts of electromagnetic radiation power from said single coaxial waveguide apportioned to respective ones of said plural concentric waveguides.

41. The reactor of claim 40 wherein said plural concentric coaxial waveguides are conically shaped having a lesser radius near said single coaxial waveguide and a greater radius facing said chamber while said single waveguide is cylindrical.
